(19) United States
(12) Patent Application Publication
(10) Pub. No.: US 2018/0179628 A1
(43) Pub. Date: Jun. 28, 2018

(54) METHOD OF MANUFACTURING SEMICONDUCTOR DEVICE, SUBSTRATE PROCESSING APPARATUS, AND RECORDING MEDIUM

(71) Applicant: HITACHI KOKUSAI ELECTRIC INC., Tokyo (JP)

(72) Inventors: Yoshitomo HASHIMOTO, Toyama-shi (JP); Yoshiro HIROSE, Toyama-shi (JP)

(73) Assignee: HITACHI KOKUSAI ELECTRIC INC., Tokyo (JP)

(21) Appl. No.: 15/902,532

(22) Filed: Feb. 22, 2018

Related U.S. Application Data
(63) Continuation of application No. PCT/JP2016/074697, filed on Aug. 24, 2016.

(30) Foreign Application Priority Data
Aug. 26, 2015 (JP) 2015-166795

(51) Int. Cl. C23C 16/44; H01L 21/31; H01L 21/67

(52) U.S. Cl. CPC C23C 16/4412; H01L 21/67; H01L 21/31; C23C 16/4401

(57) ABSTRACT

A method of manufacturing a semiconductor device includes: (a) processing a substrate accommodated in a process chamber by supplying an inert gas into a tank storing a precursor via a first supply pipe, supplying the precursor from an interior of the tank into the process chamber via a second supply pipe connected to the first supply pipe by a connection pipe, and exhausting the precursor from the interior of the process chamber; and (b) purging an interior of the first supply pipe, an interior of the connection pipe and an interior of the second supply pipe by alternately repeating: supplying a heated inert gas into the first supply pipe, the connection pipe and the second supply pipe, and exhausting the heated inert gas; and vacuumizing the interior of the first supply pipe, the interior of the connection pipe, and the interior of the second supply pipe.

### CROSS-REFERENCE TO RELATED APPLICATION(S)

This application is a Bypass Continuation Application of PCT international Application No. PCT/JP2016/074697, filed on Aug. 24, 2016, the international application being based upon and claiming the benefit of priority from Japanese Patent Application No. 2015-166795, filed on Aug. 26, 2015, the entire contents of which are incorporated herein by reference.

### TECHNICAL FIELD

The present disclosure relates to a method of manufacturing a semiconductor device, a substrate processing apparatus, and a recording medium.

### BACKGROUND

As an example of a process of manufacturing a semiconductor device, a substrate process of forming a film on the substrate is often carried out by supplying a precursor stored in a precursor tank to a substrate in a process chamber via a pipe.

In the related art, a configuration in which a heated carrier gas is supplied into a precursor tank during substrate processing has been disclosed.

In this case, when the substrate processing is repeated, a precursor or the like may remain in a pipe through which the precursor flows. In order to remove the precursor, the interior of the pipe may be purged, but this purge operation may take a long time.

### SUMMARY

Some embodiments of the present disclosure provide a technique capable of efficiently purging the interior of a pipe through which a precursor flows.

According to one embodiment of the present disclosure, a method of manufacturing a semiconductor device includes: (a) processing a substrate accommodated in a process chamber by supplying an inert gas into a tank storing a precursor via a first supply pipe, supplying the precursor from an interior of the tank into the process chamber via a second supply pipe connected to the first supply pipe by a connection pipe, and exhausting the precursor from the interior of the process chamber; and (b) purging an interior of the first supply pipe, an interior of the connection pipe and an interior of the second supply pipe by alternately repeating: supplying a heated inert gas into the first supply pipe, the connection pipe and the second supply pipe, and exhausting the heated inert gas; and vacuumizing the interior of the first supply pipe, the interior of the connection pipe, and the interior of the second supply pipe.

### BRIEF DESCRIPTION OF DRAWINGS

FIG. 1 is a schematic configuration diagram of a vertical type processing furnace of a substrate processing apparatus suitably used in one embodiment of the present disclosure, in which a portion of the processing furnace is shown in a vertical cross sectional view.

FIG. 2 is a schematic configuration diagram of the vertical type processing furnace of the substrate processing apparatus suitably used in one embodiment of the present disclosure, in which a portion of the processing furnace is shown in a cross sectional view taken along line A-A in FIG. 1.

FIG. 3 is a schematic configuration diagram of a controller of the substrate processing apparatus suitably used in one embodiment of the present disclosure, in which a control system of the controller is shown in a block diagram.

FIG. 4 is a diagram illustrating a film forming sequence according to one embodiment of the present disclosure.

FIG. 5 is a schematic configuration diagram around the processing furnace and a liquid precursor tank of the substrate processing apparatus according to one embodiment of the present disclosure.

FIG. 6 is a process flow when replacing the liquid precursor tank according to the present disclosure.

FIG. 7 is a schematic configuration diagram around a liquid precursor tank of a substrate processing apparatus suitably used in another embodiment of the present disclosure.

FIG. 8 is a schematic configuration diagram around a liquid precursor tank of a substrate processing apparatus suitably used in still another embodiment of the present disclosure.

### DETAILED DESCRIPTION

### One Embodiment of the Present Disclosure

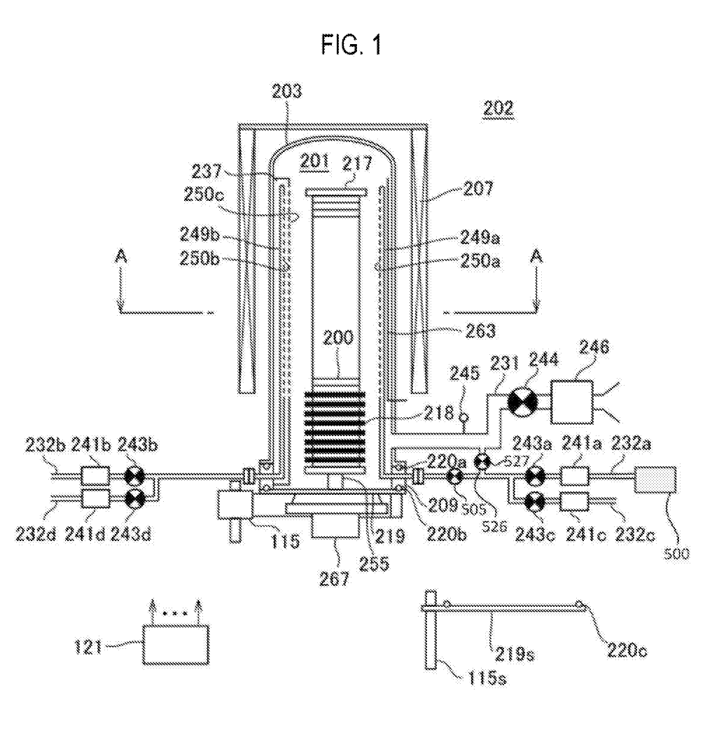

One embodiment of the present disclosure will be described with reference to FIGS. 1 to 3.

### 1) Configuration of the Substrate Processing Apparatus

As illustrated in FIG. 1, a processing furnace 202 includes a heater 207 as a heating part (heating mechanism). The heater 207 has a cylindrical shape, and is vertically installed and supported by a holding plate. The heater 207 also functions as an activation mechanism (an excitation part) configured to thermally activate (excite) a gas.

A reaction tube 203 is disposed inside the heater 207 to be concentric with the heater 207. The reaction tube 203 is made of a heat resistant material such as, for example, quartz (SiO₂), silicon carbide (SiC) or the like, and has a cylindrical shape with its upper end closed and its lower end opened. A manifold (inlet flange) 209 is disposed below the reaction tube 203 in a concentric relationship with the reaction tube 203. The manifold 209 is made of metal such as, for example, stainless steel (SUS), and has a cylindrical shape with its upper and lower ends opened. The upper end of the manifold 209 engages with the lower end of the reaction tube 203. The manifold 209 is configured to support the reaction tube 203. A O-ring 220a as a seal member is installed between the manifold 209 and the reaction tube 203. The reaction tube 203 is vertically installed like the heater 207. A processing vessel (reaction vessel) is mainly made up of the reaction tube 203 and the manifold 209. A process chamber 201 is formed in a hollow cylindrical portion of the processing vessel. The process chamber 201 is configured to accommodate wafers 200 as substrates.

Nozzles 249a and 249b are installed in the process chamber 201 so as to penetrate a sidewall of the manifold 209. Gas supply pipes 232a and 232b are connected to the nozzles 249a and 249b, respectively.

Mass flow controllers (MFCs) 241a and 241b, which are flow rate controllers (flow rate control parts), and valves 243a and 243b, which are opening/closing valves, are installed in the gas supply pipes 232a and 232b sequentially from the corresponding gas flow upstream sides, respectively. Gas supply pipes 232c and 232d, which supply an inert gas, are respectively connected to the gas supply pipes 232a and 232b at the downstream side of the valves 243a and 243b. MFCs 241c and 241d, and valves 243c and 243d are respectively installed in the gas supply pipes 232c and 232d sequentially from the corresponding gas flow upstream sides. A precursor supply part 500 as described hereinbelow is connected to a front end portion of the gas supply pipe 232a.

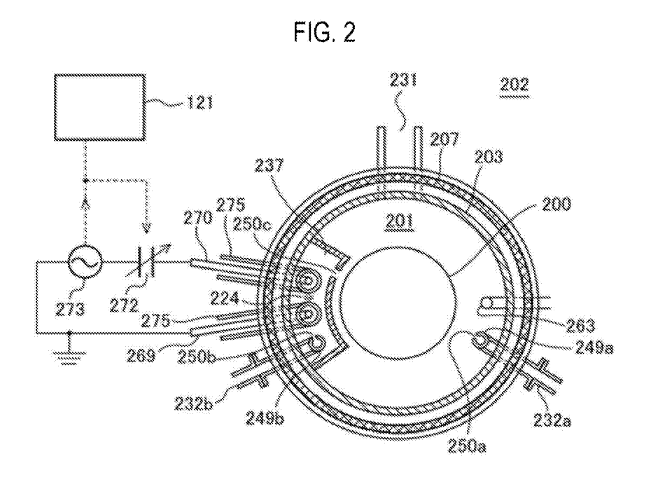

As illustrated in FIG. 2, the nozzles 249a and 249b are disposed in a space having an annular shape in a plan view between the inner wall of the reaction tube 203 and the wafers 200 such that the nozzles 249a and 249b extend upward along an arrangement direction of the wafers 200 from a lower portion of the inner wall of the reaction tube 203 to an upper portion of the inner wall of the reaction tube 203. That is, the nozzles 249a and 249b are installed in a region which horizontally surrounds the wafer arrangement region in which the wafers 200 are arranged at a lateral side of the wafer arrangement region, along the wafer arrangement region. Gas supply holes 250a and 250b for supplying a gas are formed on the side surfaces of the nozzles 249a and 249b, respectively. The gas supply holes 250a are opened toward the center of the reaction tube 203 so as to allow a gas to be supplied toward the wafers 200. The gas supply holes 250a may be formed in a plural number between the lower portion of the reaction tube 203 and the upper portion of the reaction tube 203. The gas supply holes 250b are opened toward the center of a buffer chamber 237 to be described later. The gas supply holes 250b may be formed in a plural number between the lower portion of the reaction tube 203 and the upper portion of the reaction tube 203. The aperture area and the aperture pitch of the gas supply holes 250b will be described later.

The nozzle 249b is installed within the buffer chamber 237 which is a gas diffusion space. As illustrated in FIG. 2, the buffer chamber 237 is installed in a space having an annular shape in a plan view between the inner wall of the reaction tube 203 and the wafers 200, and in a portion from the lower portion of the inner wall of the reaction tube 203 to the upper portion of the inner wall of the reaction tube 203, along the arrangement direction of the wafers 200. That is, the buffer chamber 237 is installed in the region which horizontally surrounds the wafer arrangement region at the lateral side of the wafer arrangement region, along the wafer arrangement region. Gas supply holes 250c for supplying a gas are formed in an end portion of a wall of the buffer chamber 237 which adjoins the wafers 200. The gas supply holes 250c are opened toward the center of the reaction tube 203 so as to allow a gas to be supplied toward the wafers 200. Similar to the gas supply hole 250a, the gas supply holes 250c may be formed in a plural number between the lower portion of the reaction tube 203 and the upper portion of the reaction tube 203. In the case where the differential pressure between the interior of the buffer chamber 237 and the interior of the process chamber 201 is small, the aperture area and the aperture pitch of the gas supply holes 250b may be respectively set to remain constant between the upstream side (lower portion) and the downstream side (upper portion) of the nozzle 249b. In the case where the differential pressure between the interior of the buffer chamber 237 and the interior of the process chamber 201 is large, the aperture area of the gas supply holes 250b may be set to become gradually larger from the upstream side toward the downstream side of the nozzle 249b, or the aperture pitch of the gas supply holes 250b may be set to become gradually smaller from the upstream side toward the downstream side of the nozzle 249b.

By adjusting the aperture area or the aperture pitch of the gas supply holes 250b between the upstream side and the downstream side as mentioned above, it is possible to inject a gas from the gas supply holes 250b at different flow velocities but at a substantially equal flow rate. The gas injected from the respective gas supply holes 250b is first introduced into the buffer chamber 237. This makes it possible to equalize the flow velocities of the gas within the buffer chamber 237. The gas injected from the respective gas supply holes 250b into the buffer chamber 237 is injected from the gas supply holes 250c into the process chamber 201 after the particle velocity of the gas is relaxed within the buffer chamber 237. The gas injected from the respective gas supply holes 250b into the buffer chamber 237 has a uniform flow rate and a uniform flow velocity when injected from the respective gas supply holes 250c into the process chamber 201.

A precursor, which contains a predetermined element, for example, a silane precursor gas containing silicon (Si) as a predetermined element, is supplied from the gas supply pipe 232a into the process chamber 201 via the MFC 241a, the valve 243a and the nozzle 249a.

The precursor gas refers to a gaseous precursor, for example, a precursor which remains in a gas state under room temperature and atmospheric pressure, a gas obtained by vaporizing a precursor which remains in a liquid state under room temperature and atmospheric pressure ,or a gas obtained by sublimating a solid precursor which remains in a solid state under room temperature and atmospheric pressure or by vaporizing a solution obtained by dissolving the solid precursor in a solvent. When the term “precursor” is used herein, it may refer to “a gas precursor (precursor gas) staying in a gaseous state,” “a liquid precursor staying in a liquid state,” “a solid precursor staying in a solid state,” or all of them. When the term “liquid precursor” is used herein, it may refer to a precursor which remains in a liquid state under room temperature and atmospheric pressure, a precursor obtained by dissolving a precursor which remains in a solid state under room temperature and atmospheric pressure in the form of powder in a solvent to be liquefied, or both.

As the silane precursor gas, it may be possible to use, for example, a precursor gas containing Si and an amino group (amine group), i.e., an aminosilane precursor gas. The aminosilane precursor refers to a silane precursor having an amino group and a silane precursor having an alkyl group such as a methyl group, an ethyl group, a butyl group or the like. The aminosilane precursor is a precursor containing at least Si, nitrogen (N) and carbon (C). That is, the aminosilane precursor referred to herein may be an organic precursor or may be an organic aminosilane precursor.

As the aminosilane precursor gas, it may be possible to use, for example, a bis-tert-butylaminosilane (SiH₂[NH(C₄H₉)]₂, abbreviation: BTBAS) gas. The BTBAS gas may be a precursor gas which contains one Si atom in one molecule and which has an Si—N bond, an Si—H bond, an N—C bond or the like but does not have an Si—C bond. The BTBAS gas acts as an Si source in a film forming process to be described later. As the aminosilane precursor gas, it may be possible to suitably use, other than the BTBAS gas, a tetrakis-dimethylaminosilane (Si[N(CH₃)₂]₄, abbreviation: 4DMAS) gas, a tris-dimethylaminosilane (Si[N(CH₃)₂]₃H, abbreviation: 3DMAS) gas, a bis-diethylaminosilane (Si[N(C₂H₅)₂]₂H₂, abbreviation: BDEAS) gas, or the like.

In the case of using a precursor which remains in a liquid state under room temperature and atmospheric pressure such as BTBAS, the precursor of a liquid state is vaporized by a vaporization system such as a vaporizer or a bubbler which will be described later, and is supplied as a precursor gas (BTBAS gas).

As a reactant having a different chemical structure (molecular structure) from the precursor, for example, an oxygen (O)-containing gas is supplied from the gas supply pipe 232b into the process chamber 201 via the WC 241b, the valve 243b, the nozzle 249b, and the buffer chamber 237.

The O-containing gas acts as an oxidizing agent (oxidizing gas), i.e., an O source, in the film forming process to be described later. As the O-containing gas, it may be possible to use, for example, an oxygen (O₂) gas. As the O-containing gas, it may be possible to use, other than the O₂ gas, ozone (O₃ gas), water vapor (H₂O gas) or the like. In the case of using the O₂ gas as the oxidizing agent, this gas is plasma-excited using, for example, a plasma source to be described later, and supplied as a plasma-excited gas (O₂* gas). In the case of using the O₃ gas as the oxidizing agent, the O₂ gas is converted into the O₃ gas by an ozonizer as an ozone generator and supplied as the O₃ gas. In the case of using the H₂O gas as the oxidizing agent, for example, reverse osmosis (RO) water from which an impurity has been removed using a reverse osmosis film, deionized water from which an impurity has been removed by deionization processing, pure water (or ultra pure water) such as distilled water from which an impurity has been removed by distillation using a distiller, or the like is vaporized by a vaporization system such as a vaporizer, a bubbler, a boiler or the like, and is supplied as the H₂O gas.

A nitrogen (N₂) gas as an inert gas is supplied from the gas supply pipes 232c and 232d into the process chamber 201 via the MFCs 241c and 241d, the valves 243c and 243d, the gas supply pipes 232a and 232b, the nozzles 249a and 249b, and the buffer chamber 237.

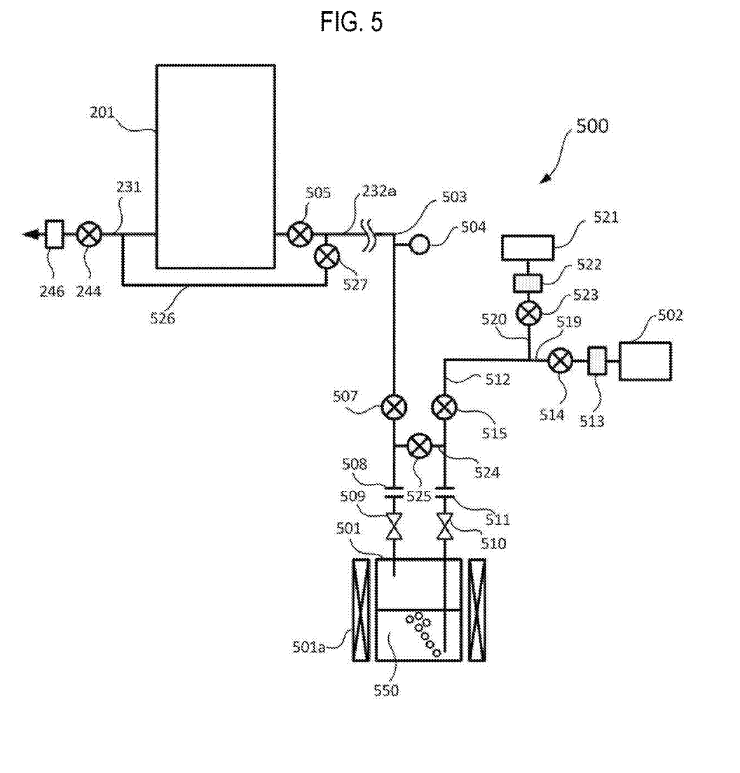

Here, the precursor supply part 500 for supplying a precursor into the gas supply pipe 232a will be described in detail with reference to FIG. 5. As illustrated in FIG. 5, a precursor supply pipe 503 as a supply pipe for supplying a precursor is connected to the gas supply pipe 232a. A pressure sensor 504 and a valve 507 are installed in the precursor supply pipe 503. In addition, a liquid precursor tank 501 as a tank that stores a liquid precursor 550 is connected to the precursor supply pipe 503 via a connection portion 508. A hand valve 509 is installed between the connection portion 508 and the liquid precursor tank 501 via the pipe.

An inert gas supply pipe 512 as a supply pipe is connected to the liquid precursor tank 501 via a connection portion 511. A hand valve 510 is installed between the connection portion 511 and the liquid precursor tank 501 via the gas supply pipe 512. A valve 515 is installed in the inert gas supply pipe 512. In addition, a carrier gas supply pipe 520 and a purge gas supply pipe 519 which are supply pipes are connected to the inert gas supply pipe 512. A carrier gas source 521, an MFC 522, and a valve 523 are installed in the carrier gas supply pipe 520 sequentially from the corresponding upstream side. A Hot-N₂ source 502, which supplies a heated inert gas, for example, a heated N₂ gas, an MFC 513 and a valve 514 are installed in the purge gas supply pipe 519 sequentially from the corresponding upstream side.

The liquid precursor tank 501 is configured as a tank (airtight container) that can store (be filled with) the liquid precursor 550 therein, and is also configured as a vaporization part that vaporizes the liquid precursor 550 by bubbling to generate a precursor gas. That is, the liquid precursor tank 501 is configured as a bubbler. A sub heater 501a for heating the liquid precursor tank 501 and the liquid precursor 550 in the liquid precursor tank 501 is installed around the liquid precursor tank 501.

By opening the valves 515 and 507 and supplying an inert gas as a carrier gas from the inert gas supply pipe 512 into the liquid precursor tank 501 with this configuration, it possible to generate a precursor gas by vaporizing the liquid precursor 550 stored in the liquid precursor tank 501 by bubbling.

A carrier gas supply system is mainly made up of the carrier gas supply pipe 520, the MFC 522, and the valve 523. The carrier gas source 521 may be included in the carrier gas supply system. A heated inert gas supply system (Hot-N₂ supply system) is mainly configured by the purge gas supply pipe 519, the MFC 513, and the valve 514. The Hot-N₂ source 502 may be included in the heated inert gas supply system. An inert gas supply system is mainly made up of the inert gas supply pipe 512 and the valve 515. The carrier gas supply system and the heated inert gas supply system may also be referred to as the inert gas supply system.

Furthermore, a connection pipe 524 is connected between the valve 507 and the connection portion 508 of the precursor supply pipe 503, and between the valve 515 and the connection portion 511 of the inert gas supply pipe 512. A valve 525 is installed in the connection pipe 524. In addition, a valve 505 is installed in the gas supply pipe 232a at the downstream side of the valve 243. A vent line 526 is installed between the valve 243a and the valve 505 of the gas supply pipe 232a so as to branch from the gas supply pipe 232a. The vent line 526 is connected to an exhaust pipe 231. A valve 527 is installed in the vent line 526. The vent line 526 is installed so as to bypass the process chamber 201. A vent system is mainly made up of the vent line 526 and the valve 527. The vent line 526 may be installed independently from the exhaust pipe 231, without being connected to the exhaust pipe 231.

With this configuration, a precursor is supplied from the interior of the liquid precursor tank 501 into the process chamber 201 via the precursor supply pipe 503 as a second supply pipe connected to the inert gas supply pipe 512 by the connection pipe 524, while supplying an inert gas into the liquid precursor tank 501 as the tank that stores a precursor, via the inert gas supply pipe 512 as a first supply pipe. The precursor is then exhausted from the interior of the process chamber 201 and the wafers 200 accommodated in the process chamber 201 are processed.

A precursor supply system is mainly made up of the gas supply pipe 232a, the MFC 241a, and the valves 243a and 505. The precursor supply part 500 and the nozzle 249a may be included in the precursor supply system. In the case where an aminosilane precursor is supplied from the gas supply pipe 232a, the precursor supply system may also be referred to as an aminosilane precursor supply system or an aminosilane precursor gas supply system. A reactant supply system is mainly configured by the gas supply pipe 232b, the MFC 241b, and the valve 243b. The nozzle 249b and the buffer chamber 237 may be included in the reactant supply system. In the case where an oxidizing agent is supplied from the gas supply pipe 232b, the reactant supply system may be referred to as an oxidant supply system, an oxidizing gas supply system, or an O-containing gas supply system. An inert gas supply system is mainly made up of the gas supply pipes 232c and 232d, the MFCs 241c and 241d, and the valves 243c and 243d.

As illustrated in FIG. 2, two rod-shaped electrodes 269 and 270 made of a conductive material and having an elongated structure are disposed within the buffer chamber 237 to extend along the arrangement direction of the wafers 200 from the lower portion of the reaction tube 203 to the upper portion of the reaction tube 203. The respective rod-shaped electrodes 269 and 270 are installed parallel to the nozzle 249b. Each of the rod-shaped electrodes 269 and 270 is covered with an electrode protection tube 275 for protection from the lower portion to the upper portion of the rod-shaped electrodes 269 and 270. One of the rod-shaped electrodes 269 and 270 is connected to a high-frequency power source 273 via a matcher 272 and the other is connected to a ground which is a reference potential. By applying radio-frequency (RF) power from the high-frequency power source 273 between the rod-shaped electrodes 269 and 270, plasma is generated in a plasma generation region 224 between the rod-shaped electrodes 269 and 270. A plasma source as a plasma generator (plasma generation part) is mainly made up of the rod-shaped electrodes 269 and 270 and the electrode protection tubes 275. The matcher 272 and the high-frequency power source 273 may be included in the plasma source. As will be described later, the plasma source functions as a plasma excitation part (activation mechanism) for plasma-exciting a gas, namely exciting (or activating) a gas in a plasma state.

The electrode protection tubes 275 have a structure allowing the respective rod-shaped electrodes 269 and 270 to be inserted into the buffer chamber 237 in a state in which the rod-shaped electrodes 269 and 270 are isolated from the internal atmosphere of the buffer chamber 237. If an O concentration within the electrode protection tubes 275 is substantially equal to an O concentration in the ambient air (atmosphere), the rod-shaped electrodes 269 and 270 respectively inserted into the electrode protection tubes 275 may be oxidized by the heat generated from the heater 207. By filling the interior of the electrode protection tubes 275 with an inert gas such as an N₂ gas or the like, or by purging the interior of the electrode protection tubes 275 with an inert gas such as an N₂ gas or the like using an inert gas purge mechanism, it is possible to reduce the O concentration within the electrode protection tubes 275, thereby preventing the rod-shaped electrodes 269 and 270 from being oxidized.

The exhaust pipe 231 as an exhaust line configured to exhaust the internal atmosphere of the process chamber 201 is installed in the reaction tube 203. A vacuum pump 246 as a vacuum exhaust device is connected to the exhaust pipe 231 via a pressure sensor 245 as a pressure detector (pressure detection part) which detects the internal pressure of the process chamber 201 and an auto pressure controller (APC) valve 244 as an exhaust valve (pressure regulation part). By opening/closing the APC valve 244, the vacuum exhaust of the interior of the process chamber 201 can be performed/stopped while operating the vacuum pump 246 and, by adjusting the opening degree of the APC valve 244 based on the pressure information detected by the pressure sensor 245, the internal pressure of the process chamber 201 can be adjusted while operating the vacuum pump 246. An exhaust system is mainly made up of the exhaust pipe 231, the APC valve 244 and the pressure sensor 245. The vacuum pump 246 may be included in the exhaust system.

A seal cap 219, which serves as a furnace opening cover configured to air-tightly seal a lower end opening of the manifold 209, is installed under the manifold 209. The seal cap 219 is made of metal such as, e.g., stainless steel or the like, and is formed in a disc shape. An O-ring 220b, which is a seal member making contact with the lower end portion of the manifold 209, is installed on an upper surface of the seal cap 219. A rotation mechanism 267 configured to rotate a boat 217, which will be described later, is installed below the seal cap 219. A rotary shaft 255 of the rotation mechanism 267, which penetrates the seal cap 219, is connected to the boat 217. The rotation mechanism 267 is configured to rotate the wafers 200 by rotating the boat 217. The seal cap 219 is configured to be vertically moved up and down by a boat elevator 115 which is an elevator mechanism installed outside the reaction tube 203. The boat elevator 115 is configured as a transfer device (transfer mechanism) which loads and unloads (transfers) the wafers 200 into and out of the process chamber 201 by moving the seal cap 219 up and down. Furthermore, a shutter 219s as a furnace opening cover capable of air-tightly sealing the lower end opening of the manifold 209 while moving the seal cap 219 down by the boat elevator 115 is installed under the manifold 209. The shutter 219s is made of metal such as, e.g., stainless steel or the like, and is formed in a disc shape. An O-ring 220c as a seal member making contact with the lower end portion of the manifold 209 is installed on an upper surface of the shutter 219s. An opening/closing operation (an up-down movement operation or a rotational movement operation) of the shutter 219s is controlled by a shutter opening/closing mechanism 115s.

The boat 217 serving as a substrate support is configured to support a plurality of wafers 200, e.g., 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 in a spaced-apart relationship. The boat 217 is made of a heat resistant material such as quartz or SiC. Heat insulating plates 218 made of a heat resistant material such as quartz or SiC are installed below the boat 217 in multiple stages.

A temperature sensor 263 serving as a temperature detector is installed in the reaction tube 203. Based on temperature information detected by the temperature sensor 263, a state of supplying electric power to the heater 207 is adjusted such that the interior of the process chamber 201 has a desired temperature distribution. The temperature sensor 263 is installed along the inner wall of the reaction tube 203.

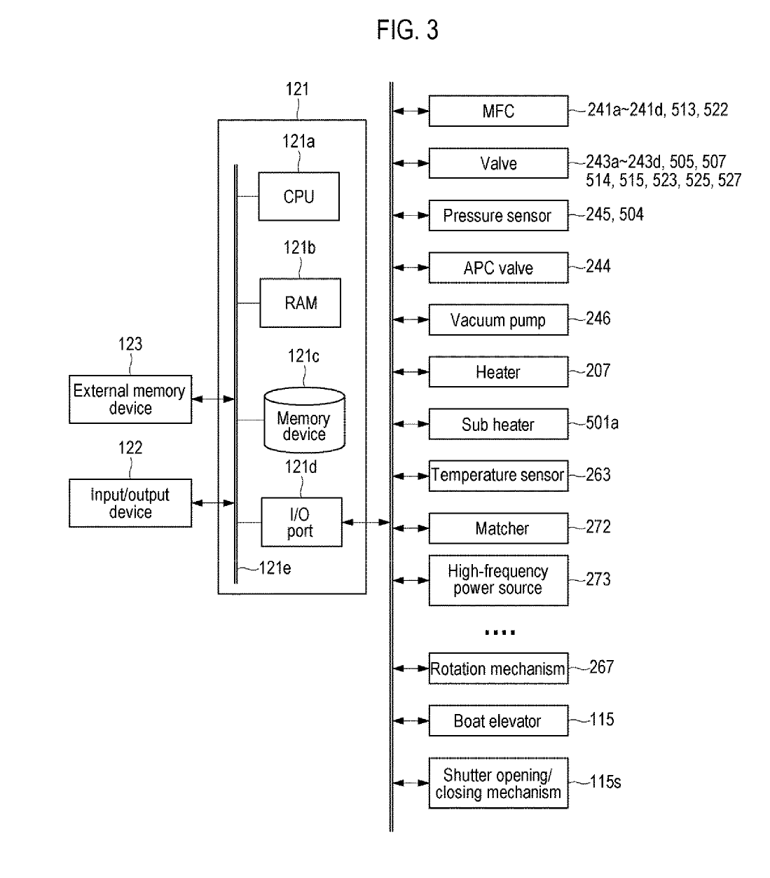

As illustrated in FIG. 3, a controller 121, which is a control part (control means), may be configured as a computer including a central processing unit (CPU) 121a, a random access memory (RAM) 121b, a memory device 121c, and an I/O port 121d. The RAM 121b, the memory device 121c and the I/O port 121d are configured to exchange data with the CPU 121a via an internal bus 121e. An input/output device 122 formed of, e.g., a touch panel or the like, is connected to the controller 121.

The memory device 121c is configured by, for example, a flash memory, a hard disk drive (HDD), or the like. A control program for controlling operations of a substrate processing apparatus, a process recipe for specifying sequences and conditions of a film forming process as described hereinbelow, a purge recipe for specifying sequences and conditions of a precursor supply part purge process as described hereinbelow, or the like is readably stored in the memory device 121c. The process recipe and the purge recipe function as a program for causing the controller 121 to execute each sequence in various processes (the film forming process or the precursor supply part purge process), as described hereinbelow, to obtain predetermined results, respectively. Hereinafter, the process recipe, the purge recipe and the control program will be generally and simply referred to as a “program”. Furthermore, the process recipe and the purge recipe will be simply referred to as a “recipe”. When the term “program” is used herein, it may indicate a case of including only the recipe, a case of including only the control program, or a case of including both the recipe and the control program. The RAM 121b is configured as a memory area (work area) in which a program or data read by the CPU 121a is temporarily stored.

The I/O port 121d is connected to the MFCs 241a to 241d, 513 and 522 the valves 243a to 243d, 505, 507, 514, 515, 523, 525 and 527, the pressure sensors 245 and 504, the APC valve 244, the vacuum pump 246, the temperature sensor 263, the heater 207, the sub heater 501a, the rotation mechanism 267, the boat elevator 115, the shutter opening/closing mechanism 115s, the matcher 272, the high-frequency power source 273, and the like, as mentioned above.

The CPU 121a is configured to read the control program from the memory device 121c and execute the same. The CPU 121a also reads the recipe from the memory device 121c according to an input of an operation command from the input/output device 122. In addition, the CPU 121a is configured to control, according to the contents of the recipe thus read, the flow rate adjusting operation of various kinds of gases by the MFCs 241a to 241d, 513 and 522, the opening/closing operation of the valves 243a to 243d, 505, 507, 514, 515, 523, 525 and 527, the opening/closing operation of the APC valve 244, the pressure regulating operation performed by the APC valve 244 based on the pressure sensor 245, the driving and stopping of the vacuum pump 246, the temperature adjusting operation performed by the heater 207 based on the temperature sensor 263, the operation of rotating the boat 217 with the rotation mechanism 267 and adjusting the rotation speed of the boat 217, the operation of moving the boat 217 up and down with the boat elevator 115, the operation of opening and closing the shutter 219s with the shutter opening/closing mechanism 115s, the impedance adjustment operation using the matcher 272, the power supply from the high-frequency power source 273, the temperature adjusting operation by the sub heater 501a, and the like.

The controller 121 may be configured by installing, on the computer, the aforementioned program stored in an external memory device 123 (for example, a magnetic disk such as a hard disk, an optical disc such as a CD, a magneto-optical disc such as an MO, or a semiconductor memory such as a USB memory). The memory device 121c or the external memory device 123 is configured as a computer-readable recording medium. Hereinafter, the memory device 121c and the external memory device 123 will be generally and simply referred to as a “recording medium.” When the term “recording medium” is used herein, it may indicate a case of including only the memory device 121c, a case of including only the external memory device 123, or a case of including both the memory device 121c and the external memory device 123. Furthermore, the program may be supplied to the computer using a communication means such as the Internet or a dedicated line, instead of using the external memory device 123.

### (2) Substrate Processing

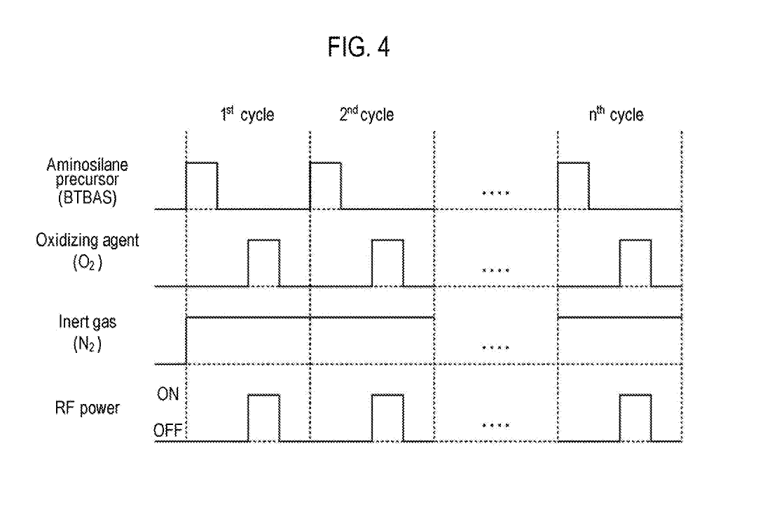

A sequence example of forming a film on a wafer 200 using the aforementioned substrate processing apparatus, which is one of the processes for manufacturing a semiconductor device, will be described below with reference to FIG. 4. In the following descriptions, the operations of the respective parts constituting the substrate processing apparatus are controlled by the controller 121.

In the substrate processing (film forming process) illustrated in FIG. 4, a silicon oxide film (SiO₂ film, hereinafter also referred to as an SiO film) is formed on a wafer 200 by non-simultaneously, i.e., non-synchronously, performing, a predetermined number of times (once or more), a step of supplying a BTBAS gas to the wafer 200 and a step of supplying a plasma-excited O₂ gas to the wafer 200. During the film forming process, the BTBAS gas and the O₂ gas are supplied under the temperature that thermally decomposes them. In the present disclosure, for the sake of convenience, the sequence of the film forming process illustrated in FIG. 4 may sometimes be denoted as follows. The same denotation will be used in other embodiments as described hereinbelow.

(BTBAS→O₂*)×n⇒SiO

When the term “wafer” is used herein, it may refer to “a wafer itself” or “a laminated body of a wafer and a predetermined layer or film formed on the surface of the wafer”. When the phrase “a surface of a wafer” is used herein, it may refer to “a surface of a wafer itself” or “a surface of a predetermined layer or film formed on a wafer. In the present disclosure, the expression “a predetermined layer is formed on a wafer” may mean that “a predetermined layer (or film) is directly formed on a surface of a wafer itself” or that “a predetermined layer is formed on a layer or film formed on a wafer. When the term “substrate” is used herein, it may be synonymous with the term “wafer.”

### (Loading Step)

If a plurality of wafers 200 is charged on the boat 217 (wafer charging), the shutter 219s is moved by the shutter opening/closing mechanism 115s to open the lower end opening of the manifold 209 (shutter opening). Thereafter, as illustrated in FIG. 1, the boat 217 supporting the plurality of wafers 200 is lifted up by the boat elevator 115 and is loaded into the process chamber 201 (boat loading). In this state, the seal cap 219 seals the lower end of the manifold 209 through the O-ring 220b.

### (Pressure Regulation and Temperature Adjustment Step)

The interior of the process chamber 201, namely the space in which the wafers 200 are located, is vacuum-exhausted (depressurization-exhausted) by the vacuum pump 246 so as to reach a desired pressure (degree of vacuum). In this operation, the internal pressure of the process chamber 201 is measured by the pressure sensor 245. The APC valve 244 is feedback-controlled based on the measured pressure information. Furthermore, the wafers 200 in the process chamber 201 are heated by the heater 207 to a desired temperature. In this operation, the state of supplying electric power to the heater 207 is feedback-controlled based on the temperature information detected by the temperature sensor 263 such that the interior of the process chamber 201 has a desired temperature distribution. The rotation of the wafers 200 by the rotation mechanism 267 begins. The exhaust and the heating of the interior of the process chamber 201, and the rotation of the wafers 200 may be continuously performed at least until the processing of the wafers 200 is completed.

However, in the case where the film forming process to be described later is performed under a temperature condition of room temperature or lower, it is not necessary to heat the interior of the process chamber 201 using the heater 207. When the processing is performed only under such a temperature, the heater 207 is unnecessary and the heater 207 need not be installed in the substrate processing apparatus. Thus, in this case, the configuration of the substrate processing apparatus can be simplified.

### (Film Formation Processing Step)

Next, the following steps 1 and 2 are sequentially performed.

### [Step 1]

At this step, a BTBAS gas is supplied to the wafer 200 within the process chamber 201. Specifically, the valves 243a and 505 are opened to allow a BTBAS gas to flow through the gas supply pipe 232a from the precursor supply part 500. The flow rate of the BTBAS gas is adjusted by the MFC 241a. The BTBAS gas is supplied into the process chamber 201 via the nozzle 249a and is exhausted from the exhaust pipe 231. At this time, the BTBAS gas is supplied to the wafer 200. Simultaneously, the valve 243c is opened to allow an N₂ gas to flow through the gas supply pipe 232c. The flow rate of the N₂ gas is adjusted by the MFC 241c. The N₂ gas is supplied into the process chamber 201 together with the BTBAS gas and is exhausted from the exhaust pipe 231. Furthermore, in order to prevent the BTBAS gas from entering the buffer chamber 237 and the nozzle 249b, the valve 243d is opened to allow the N₂ gas to flow through the gas supply pipe 232d. The N₂ gas is supplied into the process chamber 201 via the gas supply pipe 232b, the nozzle 249b and the buffer chamber 237 and is exhausted from the exhaust pipe 231.

The supply flow rate of the BTBAS gas may be set to fall within a range of, for example, 1 to 2,000 sccm, specifically 10 to 1,000 sccm. The supply flow rates of the N₂ gas may be respectively set to fall within a range of, for example, 100 to 10,000 sccm. The internal pressure of the process chamber 201 may be set to fall within a range of, for example, 1 to 2,666 Pa, specifically 67 to 1,333 Pa. The supply time period of the BTBAS gas may be set to fall within a range of, for example, 1 to 100 seconds, specifically 1 to 50 seconds.

The temperature of the wafer 200 may be set to fall within a range of, for example, 0 to 150 degrees C., specifically room temperature (25 degrees C.) to 100 degrees C., more specifically 40 to 90 degrees C. The BTBAS gas is a gas having high reactivity and that is easily adsorbed by the wafer 200 or the like. Therefore, since the BTBAS gas can be chemisorbed onto the wafer 200 even under a low temperature of, for example, about room temperature, it is possible to obtain a practical deposition rate. By setting the temperature of the wafer 200 at 150 degrees C. or lower, further 100 degrees C. or lower, or even 90 degrees C. or lower as in this embodiment, it is possible to reduce the quantity of heat applied to the wafer 200 and to satisfactorily control the thermal history of the wafer 200. In addition, if the temperature of the wafer 200 is 0 degrees C. or more, specifically room temperature or more, more specifically 40 degrees C. or more, BTBAS can be sufficiently adsorbed onto the wafer 200 and a sufficient deposition rate can be obtained. Therefore, the temperature of the wafer 200 may be set to fall within a range of 0 to 150 degrees C., specifically room temperature to 100 degrees C., more specifically 40 to 90 degrees C.

By supplying the BTBAS gas to the wafer 200 under the aforementioned conditions, an Si-containing layer having a thickness of, for example, about from less than one atomic layer to several atomic layers, may be formed on the wafer 200 (an underlying film on its surface). The Si-containing layer may be an Si layer, an adsorption layer of BTBAS, or both.

The Si layer refers to a generic term including a continuous layer made of Si, a discontinuous layer, and an Si thin film formed by overlapping these layers. The continuous layer made of Si may be referred to as an Si thin film. Si constituting the Si layer includes Si whose bond to an amino group (N) is not completely broken and Si whose bond to H is not completely broken.

The adsorption layer of BTBAS also includes a discontinuous adsorption layer in addition to a continuous adsorption layer constituted by BTBAS molecules. That is, the adsorption layer of BTBAS includes one molecular layer constituted by BTBAS molecules or an adsorption layer having a thickness of less than one molecular layer. The BTBAS molecules constituting the adsorption layer of BTBAS also include molecules in which the bond between Si and the amino group is partially broken, molecules in which the bond between Si and H is partially broken, molecules in which the bond between N and C (alkyl group) is partially broken, and the like. That is, the adsorption layer of BTBAS may be a physisorption layer of BTBAS, a chemisorption layer of BTBAS, or both.

Here, the layer having a thickness of less than one atomic layer (molecular layer) refers to an atomic layer (molecular layer) which is formed discontinuously. The layer having a thickness of one atomic layer (molecular layer) refers to an atomic layer (molecular layer) which is formed continuously. The Si-containing layer may include both the Si layer and the adsorption layer of BTBAS. However, as described above, the Si-containing layer will be represented by the expression of “one atomic layer”, “several atomic layers” or the like, and the “atomic layer” may be synonymous with the “molecular layer”.

The Si layer is formed by depositing Si on the wafer 200 under a condition that BTBAS is autolyzed (pyrolyzed). The adsorption layer of BTBAS is formed by adsorbing BTBAS on the wafer 200 under a condition that BTBAS is not autolyzed (pyrolyzed). However, in this embodiment, since the temperature of the wafer 200 is set at a low temperature of, for example, 150 degrees C. or lower, it becomes difficult for the pyrolysis of BTBAS to occur. As a result, the adsorption layer of BTBAS, rather than the Si layer, is more likely to be formed on the wafer 200.

If the thickness of the Si-containing layer formed on the wafer 200 exceeds several molecular layers, a modifying action at step 2 described later fails to reach the entire Si-containing layer. A minimum value of the thickness of the Si-containing layer is less than one atomic layer. Accordingly, it is desirable that the thickness of the Si-containing layer be approximately from less than one atomic layer to several atomic layers. By setting the thickness of the Si-containing layer at one atomic layer or less, namely one atomic layer or less than one atomic layer, it is possible to relatively increase the modifying action at step 2, which will be described later, and to shorten the time required in modifying the Si-containing layer at step 2. It is also possible to shorten the time required in forming the Si-containing layer at step 1. As a result, it is possible to shorten the processing time per one cycle and to shorten the total processing time. That is, it is possible to increase the film formation rate. Furthermore, by setting the thickness of the Si-containing layer at one atomic layer or less, it is possible to enhance the controllability of film thickness uniformity.

After the Si-containing layer is formed, the valve 243a is closed to stop supplying the BTBAS gas into the process chamber 201. At this time, the interior of the process chamber 201 is vacuum-exhausted by the vacuum pump 246 while opening the APC valve 244. Thus, the unreacted gas, the gas contributed to the formation of the Si-containing layer, or the reaction byproduct, which remains in the process chamber 201, is removed from the interior of the process chamber 201. At this time, the supply of the N₂ gas into the process chamber 201 is maintained while opening the valves 243c and 243d. The N₂ gas acts as a purge gas. This makes it possible to enhance the effect of removing the unreacted gas or the gas contributed to the formation of the Si-containing layer, which remains in the process chamber 201, from the interior of the process chamber 201.

As the precursor, it may be possible to suitably use, other than to the BTBAS gas, various kinds of aminosilane precursor gases such as a 4DMAS gas, a 3DMAS gas, a bis-dimethylaminosilane (BDMAS) gas, a BDEAS gas, a dimethylaminosilane (DMAS) gas, a diethylaminosilane (DEAS) gas, a dipropylaminosilane (DPAS) gas, a diisopropylaminosilane (DIPAS) gas, a butylaminosilane (BAS) gas or the like.

As the inert gas, it may be possible to use, other than the N₂ gas, a rare gas such as an Ar gas, an He gas, an Ne gas, a Xe gas or the like.

### [Step 2]

After step 1 is completed, a plasma-activated (excited) O₂ gas is supplied to the wafer 200. At this step, the opening/closing control of the valves 243b to 243d is performed in the same procedure as the opening/closing control of the valves 243a, 243c and 243d at step 1 to allow an O₂ gas to flow through the gas supply pipe 232b. The flow rate of the O₂ gas flowing through the gas supply pipe 232b is adjusted by the MFC 241b. The O₂ gas is supplied into the buffer chamber 237 via the nozzle 249b. At this time, high-frequency power is supplied between the rod-shaped electrodes 269 and 270. The O₂ gas supplied into the buffer chamber 237 is activated by plasma, supplied as active species into the process chamber 210 and then exhausted from the exhaust pipe 231.

The supply flow rate of the O₂ gas may be set to fall within a range of, for example, 100 to 10,000 sccm. The high-frequency power applied between the rod-shaped electrodes 269 and 270 may be set to fall within a range of, for example, 50 to 1,000 W. The internal pressure of the process chamber 201 may be set to fall within a range of, for example, 1 to 100 Pa. The supply time period of active species (O₂* or O*) obtained by plasma-exciting the O₂ gas may be set to fall within a range of, for example, 1 to 100 seconds, specifically 1 to 50 seconds. Other processing conditions may be similar to the processing conditions of step 1 described above.

By supplying the plasma-excited O₂ gas to the wafer 200 under the aforementioned conditions, the Si-containing layer formed on the wafer 200 is oxidized. At this time, Si—N bonds and S—H bonds contained in the Si-containing layer are broken by the energy of the plasma-excited O₂ gas. N and H separated from the bond with Si, and C bonded to N are desorbed from the Si-containing layer. Then, Si in the Si-containing layer, which has dangling bonds due to the desorption of N or the like, bonds with O contained in the O₂ gas to form Si—O bonds. As this reaction progresses, the Si-containing layer is changed (modified) to a layer containing Si and O, namely a silicon oxide layer (SiO layer).

In order to modify the Si-containing layer into an SiO₂ layer, it is necessary to excite the O₂ gas by plasma and then supply it. This is because, even if the O₂ gas is supplied under a non-plasma atmosphere, the energy required in oxidizing the Si-containing layer is insufficient below the temperature described above, so that it is difficult to sufficiently desorb N or C from the Si-containing layer or sufficiently oxidize the Si-containing layer to increase Si—O bonds.

After the Si-containing layer is modified to the SiO layer, the valve 243b is closed to stop the supply of the O₂ gas. Furthermore, the supply of the high-frequency power between the rod-shaped electrodes 269 and 270 is stopped. The O₂ gas or the reaction byproduct, which remains in the process chamber 201, is removed from the interior of the process chamber 201 under the same processing procedures and processing conditions as those of step 1.

As the oxidizing material, i.e., as the O-containing gas to be excited by plasma, it may be possible to use, other than the O₂ gas, a nitrous oxide (N₂O) gas, a nitrogen monoxide (NO) gas, a nitrogen dioxide (NO₂) gas, an O₃ gas, a hydrogen peroxide (H₂O₂) gas, water vapor (H₂O gas), a carbon monoxide (CO) gas, a carbon dioxide (CO₂) gas or the like.

As the inert gas, it may be possible to use, other than the N₂ gas, for example, various kinds of rare gases exemplified at step 1.

### [Performing a Predetermined Number of Times]

A cycle which non-simultaneously, i.e., non-synchronously, performs steps 1 and 2 described above is implemented a predetermined number of times (n times) (where n is an integer of 1 or more). Thus, an Si film having a predetermined composition and a predetermined thickness can be formed on the wafer 200. The aforementioned cycle may be repeated multiple times. That is, the thickness of the SiO layer formed per one cycle may be set smaller than a desired thickness and the aforementioned cycle may be repeated multiple times until the thickness of the SiO film formed by laminating the SiO layer becomes equal to the desired thickness.

### (After Purge Step and Atmospheric Pressure Return Step)

The N₂ gas is supplied from each of the gas supply pipes 232c and 232d into the process chamber 201 and is exhausted from the exhaust pipe 231. The N₂ gas acts as a purge gas. Thus, the interior of the process chamber 201 is purged with an inert gas and the gas or the like, which remains in the process chamber 201, is removed from the interior of the process chamber 201 (after purge). Thereafter, the internal atmosphere of the process chamber 201 is substituted by an inert gas (inert gas substitution). The internal pressure of the process chamber 201 is returned to an atmospheric pressure (atmospheric pressure return).

### (Unloading Step)

Thereafter, the seal cap 219 is moved down by the boat elevator 115 to open the lower end of the manifold 209. The processed wafers 200 supported on the boat 217 are unloaded from the lower end of the manifold 209 to the outside of the reaction tube 203 (boat unloading). After the boat unloading, the shutter 219s is moved so that the lower end opening of the manifold 209 is sealed by the shutter 219s through the O-ring 220c (shutter closing). The processed wafers 200 are discharged from the boat 217 (wafer discharging). After the boat discharging, the empty boat 217 is loaded into the process chamber 201.

### (3) Precursor Tank Replacement

By repeating this substrate processing, when the residual amount of the liquid precursor in the liquid precursor tank 501 reaches a predetermined amount, the replacement of the liquid precursor tank 501 is necessary.

Hereinafter, a replacement method of the liquid precursor tank 501 will be described.

### (Purge Step of Precursor Supply Part (Interior of Liquid Precursor Tank))

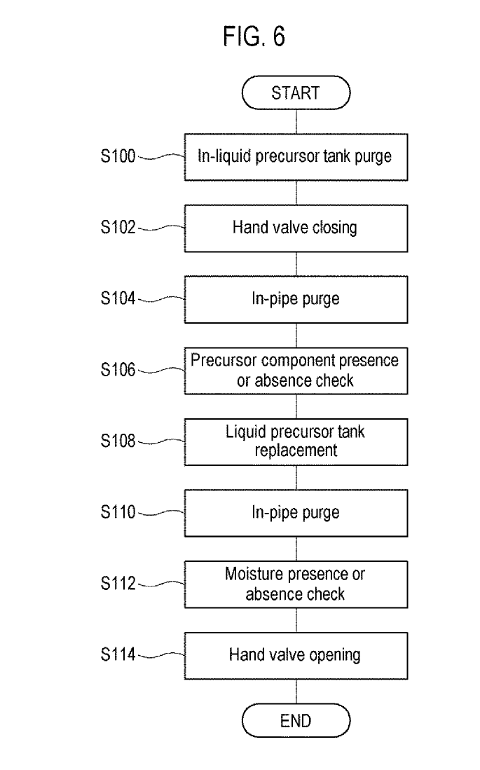

When the residual amount of the liquid precursor (BTBAS) in the liquid precursor tank 501 reaches a predetermined amount (e.g., zero), as illustrated in FIG. 6, first, the interior of the liquid precursor tank 501 is purged (S100). More specifically, the interior of the liquid precursor tank 501 and the interior of its surrounding pipes are purged. At this step, the interior of the inert gas supply pipe 512, the interior of the liquid precursor tank 501, and the interior of the precursor supply pipe 503 are purged by alternately repeating a step of supplying Hot-N₂ as a heated inert gas into the inert gas supply pipe 512 as the first supply pipe, the liquid precursor tank 501 as the tank, and the precursor supply pipe 503 as the second supply pipe through the purge gas supply pipe 519 as the third supply pipe, and exhausting it (Hot-N₂ supply step), and a step of vacuumizing the interior of the inert gas supply pipe 512, the interior of the liquid precursor tank 501, and the interior of the precursor supply pipe 503 (vacuumization step).

Specifically, in a similar manner of processing the substrate, the valves 523 and 525 are closed, and the valves 514, 515, 507, 243a and 505 are opened to supply Hot-N₂ from the Hot-N₂ source while opening the hand valves 509 and 510. Hot-N₂ is not heated inside the purge gas supply pipe 519 or the inert gas supply pipe 512 but is pre-heated outside them, i.e., in the Hot-N₂ source 502 and in such a state, is supplied into the purge gas supply pipe 519 and the inert gas supply pipe 512. Hot-N₂, which passes through the purge gas supply pipe 519 and the inert gas supply pipe 512, is supplied into the liquid precursor tank 501. Hot-N₂ supplied into the liquid precursor tank 501 is supplied into the process chamber 201 through the precursor supply pipe 503 and the gas supply pipe 232a, and is exhausted from the exhaust pipe 231 (Hot-N₂ supply step). After supplying Hot-N₂ for a predetermined period of time, the valve 514 is closed to stop the supply of Hot-N₂. Subsequently, the interior of the inert gas supply pipe 512, the interior of the liquid precursor tank 501 and the interior of the precursor supply pipe 503 are vacuumized by the vacuum pump 246 through the process chamber 201 and the exhaust pipe 231 and the vacuumization is stopped (vacuumization step). Then, the interior of the inert gas supply pipe 512, the interior of the liquid precursor tank 501, and the interior of the precursor supply pipe 503 are purged by alternately repeating the Hot-N₂ supply step and the vacuumization step. Thus, it is possible to efficiently remove residue containing the precursor adhering to and remaining in the interior of the inert gas supply pipe 512, the interior of the liquid precursor tank 501 and the interior of the precursor supply pipe 503. The residue containing the precursor includes, other than the precursor, also a substance whose precursor has been altered.

At this time, when the wafer 200 is located in the process chamber 201, at the Hot-N₂ supply step, the valve 505 is closed and the valve 527 is opened such that Hot-N₂ may be exhausted from the vent line 526 without passing through the process chamber 201. When the wafer 200 is not located in the process chamber 201, at the Hot-N₂ supply step, the valve 527 is closed and the valve 505 is opened such that Hot-N₂ may be exhausted from the exhaust pipe 231 via the process chamber 201.

### (Hand Valve Closing Step)

After the purge process of the interior of the liquid precursor tank 501 has been completed, the hand valves 509 and 510 are closed (S102).

### (Purge Step of Precursor Supply Part (Interior of Pipe))

Subsequently, the interior of the pipes around the liquid precursor tank 501 is purged (S104). At this step, the interior of the inert gas supply pipe 512, the interior of the connection pipe 524, and the interior of the precursor supply pipe 503 are purged by alternately repeating a step of supplying Hot-N₂ as a heated inert gas into the inert gas supply pipe 512 as the first supply pipe, the connection pipe 524 and the precursor supply pipe 503 as the second supply pipe through the purge gas supply pipe 519 as the third supply pipe, and exhausting it (Hot-N₂ supply step), and a step of vacuumizing the interior of the inert gas supply pipe 512, the interior of the connection pipe 524, and the interior of the precursor supply pipe 503 (vacuumization step).

Specifically, the valve 523 is closed, and the valves 514, 515, 525, 507, 243a and 505 are opened to supply Hot-N₂ from the Hot-N₂ source 502. Hot-N₂ passes through the purge gas supply pipe 519 and is supplied into the inert gas supply pipe 512, the connection pipe 524, and the precursor supply pipe 503. Hot-N₂ supplied into these pipes passes through the gas supply pipe 232a, is supplied into the process chamber 201 and is exhausted from the exhaust pipe 231 (Hot-N₂ supply step). After supplying Hot-N₂ for a predetermined time, the valve 514 is closed to stop the supply of Hot-N₂. Subsequently, the interior of the inert gas supply pipe 512, the interior of the connection pipe 524 and the interior of the precursor supply pipe 503 are vacuumized by the vacuum pump 246 through the process chamber 201 and the exhaust pipe 231 and the vacuuming is stopped (vacuumization step). Then, the interior of the inert gas supply pipe 512, the interior of the connection pipe 524 and the interior of the precursor supply pipe 503 are purged by alternately repeating the Hot-N₂ supply step and the vacuumization step. Thus, it is possible to efficiently remove residue containing the precursor adhering to and remaining in the interior of the inert gas supply pipe 512, the interior of the connection pipe 524, and the interior of the precursor supply pipe 503. The residue containing the precursor includes, other than the precursor, also a substance whose precursor has been altered.

At this time, similar to the step of purging the interior of the liquid precursor tank 501, Hot-N₂ may be exhausted at the Hot-N₂ supply step. That is, when the wafer 200 is located in the process chamber 201, Hot-N₂ may be exhausted from the vent line 526 without passing through the process chamber 201 at the Hot-N₂ supply step, and when the wafer 200 is not located in the process chamber 201, Hot-N₂ may be exhausted from the exhaust pipe 231 through the process chamber 201 at the Hot-N₂ supply step. In either case, Hot-N₂ may be exhausted from the vent line 526. Furthermore, when Hot-N₂ is exhausted from the vent line 526, the vacuumization may be performed using the vent line 526 even at the vacuumization step. These steps are not only the same at the purge step of the interior of pipe but also at the purge step of the interior of the precursor tank.

### (Precursor Component Presence or Absence Check Step)

After the purge process of the interior of the pipes is completed, the presence or absence of the precursor component in the pipes is checked using the pressure sensor 504 (S106). At this step, the interior of the pipes, the interior of the inert gas supply pipe 512, the interior of the connection pipe 524 and the interior of the precursor supply pipe 503 are vacuumized and then the vacuumization is stopped. At that time, the pressure sensor 504 monitors the internal pressure of the pipes and determines the presence or absence of the precursor component depending on whether or not the interior of the pipes can be vacuumized to a predetermined pressure (can reach a predetermined degree of vacuum). If the interior of the pipe is not vacuumized to a predetermined pressure, it can be determined that the precursor component remains (the residual precursor is discharged), and if the interior of the pipes can be vacuumized to a predetermined pressure, it can be determined that there is no precursor component. In addition, after the interior of the pipes is vacuumized, the pressure sensor 504 may monitor the internal pressure of the pipes and determine the presence or absence of the precursor component depending on whether there is a pressure fluctuation (pressure rise) while maintaining the state for a predetermined period of time (build-up method). When the pressure rise occurs until the predetermined period of time has elapsed, it can be determined that the precursor component remains (the residual precursor is discharged), and when the pressure rise does not occur even after the lapse of the predetermined period of time, it can be determined that there is no precursor component. When it is determined that the precursor component remains in the pipes, it can be determined that the liquid precursor tank 501 cannot be detached. In this case, the purge step of the pipe interior is performed again. When it is determined that there is no precursor component in the pipe, it can be determined that the liquid precursor tank 501 can be detached.

### (Liquid Precursor Tank Replacement Step)

After checking that there is no precursor component in the pipes, the replacement of the liquid precursor tank 501 is performed (S108). The liquid precursor tank 501 is detached from the connection portions 508 and 511, and the new liquid precursor tank 501 is attached to the connection portions 508 and 511.

### (Purge Step of Precursor Supply Part (Pipe Interior))

When replacing the liquid precursor tank 501, portions of the pipes, namely the interior of the inert gas supply pipe 512 at the downstream side of the valve 515, the connection pipe 524 and the precursor supply pipe 503 at the upstream side of the valve 507 is opened to the atmosphere and exposed to the atmosphere. As a result, the residue containing moisture (H₂O) in the atmosphere will adhere to the interior of these pipes. In addition to the moisture contained in the atmosphere, the residue containing moisture may contain organic substances contained in the atmosphere. In order to remove the residue containing the moisture adhering to the interior of the pipes, the interior of the pipes is purged after replacing the liquid precursor tank (S110). At this step, the interior of the pipes is purged in the same procedure as that of the purge step of the pipe interior performed before replacing the liquid precursor tank. That is, at this step, the interior of the inert gas supply pipe 512, the interior of the connection pipe 524, and the interior of the precursor supply pipe 503 are purged by alternately repeating a step of supplying Hot-N₂ as a heated inert gas into the inert gas supply pipe 512 as the first supply pipe, the connection pipe 524, the precursor supply pipe 503 as the second supply pipe through the purge gas supply pipe 519 as the third supply pipe, and exhausting it (Hot-N₂ supply step), and a step of vacuumizing the interior of the inert gas supply pipe 512, the interior of the connection pipe 524 and the interior of the precursor supply pipe 503 (vacuumization step). Specifically, the opening/closing control of the valves, the selection of the exhaust line (the exhaust pipe 231 or the vent line 526), or the like is performed in the same manner as those of the purge step of the pipe interior performed before replacement of the liquid precursor tank. Thus, it is possible to efficiently remove the residue containing moisture adhering to the interior of the inert gas supply pipe 512, the interior of the connection pipe 524 and the interior of the precursor supply pipe 503.

### (Moisture Presence or Absence Check Step)

After the purge process of the interior of the pipes has been completed, the presence or absence of moisture in the pipes is checked using the pressure sensor 504 (S112). At this step, the presence or absence of moisture in the pipes is checked by the same principle and procedure as those of the step of checking the presence or absence of a precursor component. In this case, it may be considered that the “precursor” in the description of the step of checking the presence or absence of a precursor component described above is replaced with the “moisture”. For example, the presence or absence of moisture in the pipes is determined by the degree of vacuum, which reaches the interior of the pipes when vacuumizing, or the build-up method or the like. If it is determined that the moisture remains in the pipes, the purge step of the pipe interior is performed again. If it is determined that there is no moisture in the pipes, it can be determined that the replaced liquid precursor tank 501 and the pipes can communicate with each other.

### (Hand Valve Opening Step)

After checking that there is no moisture in the pipes, the hand valves 509 and 510 are opened (S114). Thus, the replaced liquid precursor tank 501 and the pipes are opened (communicate with each other).

As described above, when the interior of the liquid precursor tank and the interior of the pipes are purged, it is possible to significantly improve the purge efficiency by the combination of supplying Hot-N₂ to a target portion to be purged and vacuumizing (withdrawing) the target portion to be purged. In addition, it is possible to significantly improve the purge efficiency of the pipes and the precursor tank having the complex path like the vicinity of the connection pipe 524.

In particular, when a liquid precursor having a low vapor pressure is used, it is sometimes difficult to remove the precursor from the interior of the pipes or the like. In this case, it takes a long time for purge process to complete causing the downtime of the substrate processing apparatus to increase. Generally, although there is a technique of heating a liquid precursor tank and its surrounding pipes with a heater from the outside, this technique heats only the inner wall of the liquid precursor tank and the pipes. Therefore, when the shapes are complicated, the way of winding the heater around the pipes or the like may not become uniform. Thus, there is a case where a portion (cold spot) where the heating is insufficient is generated on the inner wall of the pipes or the like and the liquid precursor remains in the pipes or the like. Furthermore, in this case, even when the interior of the pipes is purged while heating the pipes, it may take a long time for the purge process to complete. According to the present disclosure, even when the liquid precursor having a low vapor pressure is used as described above, it is possible to significantly improve the purge efficiency of the interior of the pipes or the like, and to shorten the downtime of the substrate processing apparatus.

At the Hot-N₂ supply step, it is desirable that the temperature of Hot-N₂ be set to be higher than the temperature of the inert gas supplied into the liquid precursor tank 501 at the film formation processing step, for example, to fall within a range of 30 to 250 degrees C., specifically 100 to 150 degrees C. If the temperature of Hot-N₂ is lower than 30 degrees C., the purge effect using the Hot-N₂ and the purge effect using unheated N₂ do not change so much. By setting the temperature of Hot-N₂ to become 30 degrees C. or more, it is possible to enhance the purge effect, i.e., the removal efficiency and the removal effect of the precursor remaining in the pipes or the like. By setting the temperature of Hot-N₂ to become 100 degrees C. or more, it is possible to further enhance this effect. Furthermore, when the temperature of Hot-N₂ exceeds 250 degrees C., the valves, MFCs, or the like may not normally operate. By setting the temperature of Hot-N₂ at 250 degrees C. or lower, it is possible to prevent the malfunction of the valves, the MFCs or the like. By setting the temperature of Hot-N₂ at 150 degrees C. or lower, it is possible to reliably prevent the malfunction of the valves, the MFCs or the like. Therefore, it is desirable that the temperature of Hot-N₂ be set to fall within a range of 30 to 250 degrees C., specifically 100 to 150 degrees C.

At the Hot-N₂ supply step, it is desirable that the supply flow rate of Hot-N₂ be set to fall within a range of, for example, 1 to 20 slm, specifically 2 to 10 slm. If the supply flow rate of Hot-N₂ is less than 1 slm, when alternately repeating the Hot-N₂ supply step and the vacuumization step, a pressure difference (pressure fluctuation) may not be sufficiently generated in the pipes or the like at the Hot-N₂ supply step and the vacuumization step. By setting the supply flow rate of Hot-N₂ at 1 slm or more, it is possible to generate a sufficient pressure difference in the pipes or the like between the Hot-N₂ supply step and the vacuumization step, and to sufficiently enhance the removal efficiency and the removal effect of the precursor remaining in the pipes or the like. By setting the supply flow rate of Hot-N₂ at 2 slm or more, it is possible to further enhance this effect. In addition, if the supply flow rate of Hot-N₂ exceeds 20 slm, the vacuum pump 246 may be overloaded and the purge effect may also be saturated. By setting the supply flow rate of Hot-N₂ at 20 slm or less, it is possible to reduce the load on the vacuum pump 246 and to prevent the waste of Hot-N₂. Therefore, it is desirable that the flow rate of Hot-N₂ be set to fall within a range of 1 to 20 slm, specifically 2 to 10 slm.

As the heated inert gas used at the Hot-N₂ supply step, it may be possible to use, other than Hot-N₂, a rare gas such as Ar, He, Ne, Kr, Xe (Hot-Ar, Hot-He, Hot-Ne, Hot-Kr, or Hot-Xe) or the like, which is heated. Since the rare gas such as Ar and He has a smaller molecular size than N₂, it can enter even a narrow place where N₂ cannot enter. Thus, it is possible to perform the purge process more finely than the case of using N₂.

(4) Effects according to the Present Embodiment

According to the present embodiment, one or more effects as set forth below may be achieved.

(a) By intermittently and alternately performing the supply and vacuumization of Hot-N₂ when the interior of the liquid precursor tank and the interior of the pipes around the tank are purged before and after replacing the tank, it is possible to significantly improve the purge effect, and to remarkably improve a reduction in purge time. This makes it possible to shorten the downtime of the substrate processing apparatus, and further to improve the productivity of substrate processing.

(b) For example, in the case where the pipes are heated by the heater from the outside at the time of purging the interior of the pipes, only inner walls of the pipes are heated. When the pipe paths are complicated, it is considered that an insufficiently heated portion may be generated and the residual precursor or residual moisture may not be sufficiently removed. In the case of the present disclosure, even when the pipe paths are complicated, it is possible to uniformly heat the entire pipe route, and to sufficiently remove the residual precursor and residual moisture. That is, according to the present disclosure, it is possible to obtain the effect that cannot be obtained when the pipes are heated from the outside.

(c) Since the purge gas supply pipe 519 is connected to the inert gas supply pipe 512, even when the precursor flows back into (enters) the inert gas supply pipe 512 and adheres thereto, it is possible to more efficiently remove this by purging the interior of the pipes. Furthermore, since the carrier gas supply pipe 520 is also connected to the inert gas supply pipe 512, an unheated inert gas or a heated inert gas can be selectively supplied into the inert gas supply pipe 512.

The aforementioned effects can be similarly obtained even in the case of using a precursor other than BTBAS or the case of using a reactant other than an O₂ gas during the film forming process. In addition, the aforementioned effects can be similarly obtained even when an inert gas other than an N₂ gas is used for purging the interior of the liquid precursor tank and the interior of the pipes.

### Other Embodiments of the Present Disclosure

While an embodiment of the present disclosure has been specifically described above, the present disclosure is not limited to the aforementioned embodiment and may be differently modified without departing from the spirit of the present disclosure.

For example, in the aforementioned embodiment, there has been described an example in which the interior of the liquid precursor tank and the interior of the pipes are purged before replacing the liquid precursor tank 501. The present disclosure is not limited to the embodiment but only the interior of the pipes may be purged without purging the interior of the liquid precursor tank before replacing the liquid precursor tank 501. By purging the interior of the pipes, it is also possible to purge the pipe of the liquid precursor tank and the connection portion. In this manner, the purge of the interior of the liquid precursor tank may not be omitted.

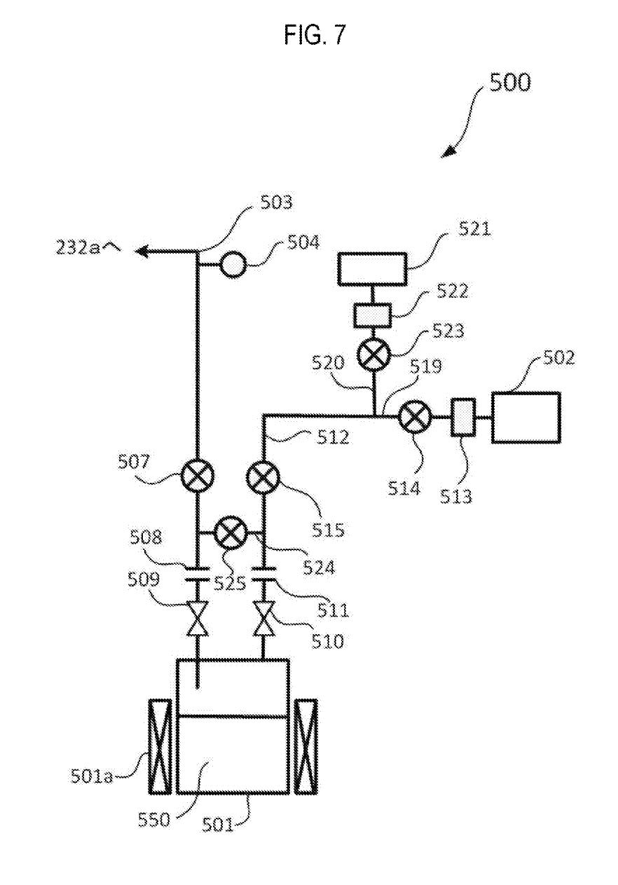

Furthermore, for example, in the aforementioned embodiment, there has been described an example in which the vaporization system that vaporizes a liquid precursor by the bubbler is used. The present disclosure is not limited to the example and a vaporization system that heats and vaporizes a liquid precursor may be used. An example of a configuration around the liquid precursor tank in this case is illustrated in FIG. 7. In this vaporization system, the interior of the liquid precursor tank 501 is heated by the sub heater 501a to vaporize the liquid precursor 550 in the liquid precursor tank 501. In this state, the valves 514 and 525 are closed, and the valves 523, 515, 507, 243a and 505 are opened to supply an N₂ gas from the carrier gas source 521 into the liquid precursor tank 501 such that the vaporized precursor is supplied into the process chamber 201 via the precursor supply pipe 503 and the gas supply pipe 232a. When replacing the liquid precursor tank 501, the interior of the liquid precursor tank and the interior of the pipe may be purged in the same manner as that of the aforementioned embodiment.

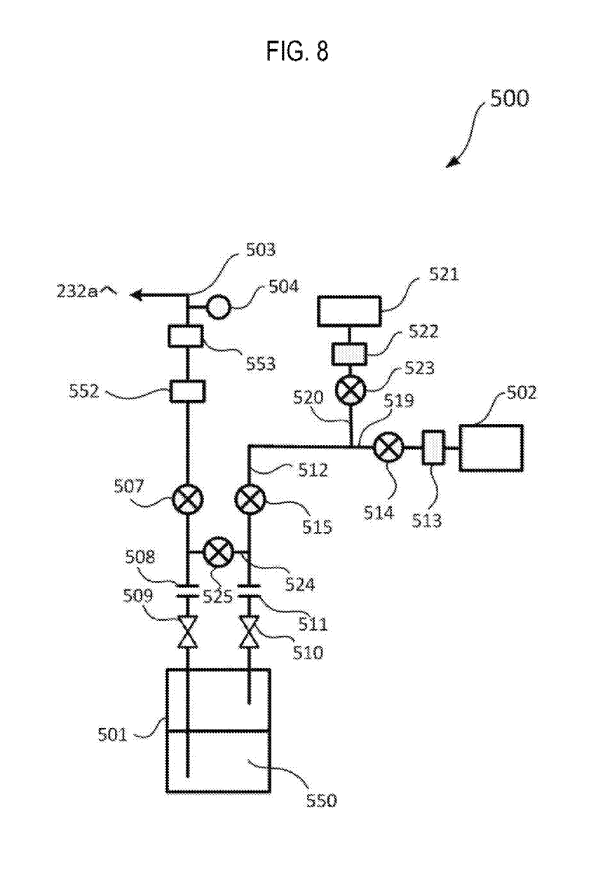

Furthermore, for example, in the aforementioned embodiment, there has been described an example in which the vaporization system that vaporizes a liquid precursor by the bubbler is used. The present disclosure is not limited to the example, and a vaporization system that vaporizes a liquid precursor by a vaporizer may be used. An example of a configuration around the liquid precursor tank in this case is illustrated in FIG. 8. A vaporization operation in this vaporization system is as follows. That is, the valves 514 and 525 are closed, and the valves 523, 515, 507, 243a and 505 are opened to supply an N₂ gas from the carrier gas source 521 to the space above the liquid precursor 550 in the liquid precursor tank 501. Thus, the liquid precursor 550 in the liquid precursor tank 501 is pushed out into the precursor supply pipe 503. The flow rate of the liquid precursor 550 pushed out into the precursor supply pipe 503 is adjusted in a liquid state by a liquid mass flow controller (LMFC) 552 as a liquid flow rate controller (liquid flow rate control part), and thereafter, is vaporized by the vaporizer 553 and supplied into the process chamber 201 via the gas supply pipe 232a. When replacing the liquid precursor tank 501, the interior of the liquid precursor tank and the interior of the pipes may be purged in the same manner as that of the aforementioned embodiment.

Furthermore, for example, in the aforementioned embodiment, there has been an example in which an aminosilane precursor is used as the precursor gas. The present disclosure is not limited to the example, and a precursor other than the aminosilane precursor, for example, a halosilane precursor, may be used. As the halosilane precursor, it may be possible to use a chlorosilane precursor, a fluorosilane precursor, a bromosilane precursor or the like. The processing conditions at this time may be similar to, for example, the processing conditions as those of the aforementioned embodiment.

For example, as the halosilane precursor, it may be possible to use a chlorosilane precursor gas such as a monochlorosilane (SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane (SiCl₄, abbreviation: STC) gas, a hexachlorodisilane (Si₂Cl₆, abbreviation: HCDS) gas, an octachlorotrisilane (Si₃Cl₈, abbreviation: OCTS) gas or the like. As another halosilane precursor, it may be possible to use an organohalosilane precursor gas, for example, an alkylenhalosilane precursor gas such as an ethylene bis (trichlorosilane) gas, i.e., a 1,2-bis (trichlorosilyl) ethane ((SiCl₃)₂C₂H₄, abbreviation: BTCSE) gas, a methylene bis (trichlorosilane) gas, i.e., a bis (trichlorosilyl) methane ((SiCl₃)₂CH₂, abbreviation: BTCSM) gas or the like, or an alkylhalosilane precursor gas such as a 1,1,2,2-tetrachloro-1,2-dimethyldisilane (CH₃)₂Si₂Cl₄, abbreviation: TCDMDS) gas, a 1,2-dichloro-1,1,2,2-tetramethyldisilane ((CH₃)₄Si₂Cl₂, abbreviation: DCTMDS) gas, a 1-monochloro- 1,1,2,2,2-pentamethyldisilane ((CH₃)₅Si₂Cl, abbreviation MCPMDS) gas or the like. As another halosilane precursor, it may be possible to use a fluorosilane precursor gas such as a trifluorosilane (SiHF₃, abbreviation: TFS) gas, a tetrafluorosilane (SiF₄, abbreviation: STF) gas or the like, or a bromosilane precursor gas such as a tribromosilane (SiHBr₃, abbreviation: TBS) gas, a tetrabromosilane (SiBr₄, abbreviation: STB) gas or the like.

As the precursor gas, it may be possible to use, in addition to these gases, an inorganic silane precursor gas such as a trisilane (Si₃H₈) gas, a tetrasilane (Si₄H₁₀) gas, a pentasilane (Si₅H₁₂) gas, a hexasilane (Si₆H₁₄) gas or the like, or an organic silane precursor gas such as a 1,4-disilabutane (Si₂C₂H₁₀) gas or the like.

Furthermore, for example, in the aforementioned embodiment, there has been described an example in which a plasma-excited O₂ gas is used as a reactant. The present disclosure is not limited to the example and an oxidizing agent may be used, without being plasma-excited, for example, by the film forming sequences illustrated below. In this case, as the oxidizing agent, it may be possible to use an O₃ gas or an H₂O gas. In this case, the temperature of the wafer 200 may be set to fall within a range of, for example, 100 degrees C. to 700 degrees C., specifically 100 degrees C. to 600 degrees C.

(BDEAS→O₃)×n⇒SiO

(BDEAS→H₂O)×n⇒SiO

By using the silicon-based insulating film formed by the method of the aforementioned embodiment as a sidewall spacer, it is possible to provide a device forming technique with less leakage current and excellent processability. Furthermore, by using the aforementioned silicon-based insulating film as an etching stopper, it is possible to provide a device forming technique with excellent processability. Moreover, in some embodiments, since the silicon-based insulating film can be formed without using a plasma, the present disclosure may be applied to, e.g., a process that concerns plasma damage such as an SADP film of DPT.

In the aforementioned embodiment or the like, there has been described an example in which an SiO₂ film is formed on the wafer 200. The present disclosure is not limited to the example. For example, the present disclosure may also be applied to a case where an Si-based thin film such as a silicon oxycarbide film (SiOC film), a silicon oxycarbonitride film (SiOCN film), a silicon oxynitride film (SiON film), a silicon nitride film (SiN film), a silicon carbonitride film (SiCN film), a silicon boronitride film (SiBN film), a silicon boron carbonitride film (SiBCN film), a silicon film (Si film) or the like is formed on the wafer 200, for example, by the film forming sequences denoted below. At this time, the temperature of the wafer 200 may be set to fall within a range of 300 degrees C. to 700 degrees C. Other processing conditions may be similar to the processing conditions of the aforementioned embodiment.

(HCDS→TEA→O₂)×n⇒SiOC

(HCDS→C₃H₆O₂→NH₃)×n⇒SiOCN

(HCDS→NH₃→O₂)×n⇒SiON

(HCDS→NH₃)×n⇒SiN

(HCDS→C₃H₆→NH₃)×n⇒SiCN

(HCDS→BCl₃→NH₃)×n→SiBN

(HCDS→C₃H₆→BCl₃→NH₃)×n⇒SiBCN

(HCDS→DIPAS)×n⇒Si

The present disclosure may be suitably applied to a case where a film containing, as a precursor element, a metal element such as titanium (Ti), zirconium (Zr), hafnium (Hf), tantalum (Ta), niobium (Nb), molybdenum (Mo), tungsten (W), yttrium (Y), strontium (Sr), aluminum (Al) or the like, i.e., a metal thin film, is formed on the wafer 200.

The present disclosure may also be applied to, e.g., a case where a TiO film, an HfO film, a Zr film or the like is formed on the wafer 200 by the film forming sequences denoted below using a tetrakis (dimethylamino) titanium (Ti[N(CH₃)₂]₄, abbreviation: TDMAT) gas, a tetrakis (dimethylamino) hafnium (Hf[N(C₂H₅)(CH₃)]₄, abbreviation: TEMAH) gas, a tetrakis (ethylmethylamino) zirconium (Zr[N(C₂H₅)(CH₃)]₄, abbreviation: TEMAZ) gas, a trimethylaluminum (Al(CH₃)₃, abbreviation: TMA) gas, a titanium tetrachloride (TiCl₄) gas, a hafnium tetrachloride (HfCl₄) gas or the like, as the precursor gas. At this time, the temperature of the wafer 200 may be set to fall within a range of 100 degrees C. to 600 degrees C. Other processing conditions may be similar to the processing conditions of the aforementioned embodiment.

(TDMAT→O₂*)×n⇒TiO₂

(TEMAH→O₂*)×n⇒HfO

(TEMAZ→O₂*)×n⇒ZrO

(TMA→O₂*)×n⇒AlO

(TiCl₄→H₂O)×n⇒TiO

(HfCl₄→H₂O)×n⇒HfO

(ZrCl₄→H₂O)×n⇒ZrO

(TMA→H₂O)×n⇒AlO

(TiCl₄→NH₃)×n⇒TiN

(HfCl₄→NH₃)×n⇒HfN

(ZrCl₄→NH₃)×n⇒ZrN

TMA→NH₃)×n⇒AlN

That is, the present disclosure may be suitably applied to a case where a liquid precursor tank is replaced or a metal film or a purge process of the precursor supply part is performed after performing a process of forming a semiconductor film. The processing procedures and processing conditions of the purge process of the precursor supply part may be similar to those of the purge process of the precursor supply part illustrated in the aforementioned embodiment. Even in these cases, the same effects as those of the aforementioned embodiment may be achieved.

Recipes used in a film forming process and a purge process of a precursor supply part may be prepared individually according to the processing contents and may be stored in the memory device 121c via a telecommunication line or the external memory device 123. Moreover, at the start of processing, the CPU 121a may properly select an appropriate recipe from the recipes stored in the memory device 121c according to the processing contents. Thus, it is possible for a single substrate processing apparatus to form films of different kinds, composition ratios, qualities and thicknesses with enhanced reproducibility. In addition, it is possible to reduce an operator's burden and to quickly start the substrate processing while avoiding an operation error.

The recipes mentioned above are not limited to newly-prepared ones but may be prepared by, for example, modifying the existing recipes, which have been already installed in the substrate processing apparatus. When modifying the recipes, the modified recipes may be installed in the substrate processing apparatus via a telecommunication line or a recording medium storing the recipes. In addition, the existing recipes, which have been already installed in the substrate processing apparatus, may be directly modified by operating the input/output device 122 of the existing substrate processing apparatus.

In the aforementioned embodiment, there has been described an example in which films are formed using a batch-type substrate processing apparatus capable of processing a plurality of substrates at a time. The present disclosure is not limited to the aforementioned embodiment but may be appropriately applied to, e.g., a case where films are formed using a single-wafer-type substrate processing apparatus capable of processing a single substrate or several substrates at a time. In addition, in the aforementioned embodiment, there has been described an example in which films are formed using a substrate processing apparatus provided with a hot-wall-type processing furnace. The present disclosure is not limited to the aforementioned embodiment but may be appropriately applied to a case where films are formed using a substrate processing apparatus provided with a cold-wall-type processing furnace. Even in the case of using these substrate processing apparatuses, the film forming process and the purge process of the precursor supply part may be performed under the processing conditions similar to those of the aforementioned embodiment, and the same effects as those of the aforementioned embodiment may be achieved.

The aforementioned embodiments may be appropriately combined with one another. In addition, the processing conditions used at this time may be similar to, for example, the processing conditions of the aforementioned embodiment.

According to the present disclosure in some embodiments, it is possible to efficiently purge the interior of a pipe through which a precursor flows.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising:
(a) processing a substrate accommodated in a process chamber by supplying an inert gas into a tank storing a precursor via a first supply pipe, supplying the precursor from an interior of the tank into the process chamber via a second supply pipe connected to the first supply pipe by a connection pipe, and exhausting the precursor from the interior of the process chamber; and
(b) purging an interior of the first supply pipe, an interior of the connection pipe and an interior of the second supply pipe by alternately repeating:
supplying a heated inert gas into the first supply pipe, the connection pipe and the second supply pipe, and exhausting the heated inert gas; and
vacuumizing the interior of the first supply pipe, the interior of the connection pipe, and the interior of the second supply pipe.

2. The method of claim 1, wherein a residue containing the precursor, which adheres to and remains in at least one of the interior of the first supply pipe, the interior of the connection pipe and the interior of the second supply pipe, is removed in (b).

3. The method of claim 1, further comprising:
(c) purging the interior of the first supply pipe, the interior of the tank and the interior of the second supply pipe by alternately repeating:
supplying a heated inert gas into the first supply pipe, the tank and the second supply pipe, and exhausting the heated inert gas; and
vacuumizing the interior of the first supply pipe, the interior of the tank and the interior of the second supply pipe.

4. The method of claim 3, wherein a residue containing the precursor, which adheres to and remains in at least one of the interior of the first supply pipe, the interior of the tank and the interior of the second supply pipe, is removed in (c).

5. The method of claim 1, further comprising replacing the tank after (b).

6. The method of claim 5, wherein (b) is further performed after the act of replacing the tank.

7. The method of claim 6, wherein a residue containing moisture, which adheres to and remains in at least one of the interior of the first supply pipe, the interior of the connection pipe and the interior of the second supply pipe when replacing the tank, is removed in (b) performed after the act of replacing the tank.

8. The method of claim 1, wherein an inert gas, which is heated outside the first supply pipe, the connection pipe and the second supply pipe, is supplied into the first supply pipe, the connection pipe and the second supply pipe in (b).

9. The method of claim 3, wherein (c) is performed before (b).

10. The method of claim 3, wherein the heated inert gas, which is supplied in at least one of (b) and (c), is heated to become a temperature higher than a temperature of the inert gas supplied into the tank in (a).

11. The method of claim 1, wherein a third supply pipe configured to supply the heated inert gas is connected to the first supply pipe.

12. The method of claim 1, wherein the heated inert gas is supplied into the first supply pipe, circulated in the first supply pipe, the connection pipe and the second supply pipe, and exhausted via the interior of the process chamber, in (b).

13. The method of claim 3, wherein the heated inert gas is supplied into the first supply pipe, circulated in the first supply pipe, the tank and the second supply pipe, and exhausted via the interior of the process chamber, in (c).

14. The method of claim 1, wherein the heated inert gas is supplied into the first supply pipe, circulated in the first supply pipe, the connection pipe and the second supply pipe, and exhausted without passing through the process chamber, in (b).

15. The method of claim 3, wherein the heated inert gas is supplied into the first supply pipe, circulated in the first supply pipe, the tank and the second supply pipe, and exhausted without passing through the process chamber, in (c).

16. The method of claim 1, wherein the precursor includes a precursor in a liquid state at room temperature and atmospheric pressure, or a precursor in a liquid state obtained by dissolving a precursor in a solid state at room temperature and atmospheric pressure in a solvent.

17. The method of claim 16, wherein a vaporization part configured to vaporize the precursor in a liquid state is installed in the tank or the second supply pipe.

18. The method of claim 1, wherein (a) includes forming a film on the substrate by simultaneously or non-simultaneously performing:
supplying the precursor into the process chamber and exhausting the precursor from the interior of the process chamber; and
supplying a reactant into the process chamber and exhausting the reactant from the interior of the process chamber.

19. A substrate processing apparatus, comprising:
a process chamber configured to accommodate a substrate;
a precursor supply system configured to supply an inert gas into a tank storing a precursor via a first supply pipe, supply the precursor from an interior of the tank into the process chamber via a second supply pipe connected to the first supply pipe by a connection pipe;
a heated inert gas supply system configured to supply a heated inert gas into the first supply pipe;
an exhaust system configured to vacuum-exhaust the interior of the process chamber; and
a controller configured to control the precursor supply system, the heated inert gas supply system and the exhaust system so as to perform:
(a) processing a substrate accommodated in the process chamber by supplying the inert gas into the tank storing the precursor via the first supply pipe, supplying the precursor from the interior of the tank into the process chamber via the second supply pipe, and exhausting the precursor from the interior of the process chamber; and
(b) purging the interior of the first supply pipe, the interior of the connection pipe and the interior of the second supply pipe by alternately repeating:
supplying a heated inert gas into the first supply pipe, the connection pipe and the second supply pipe, and exhausting the heated inert gas; and
vacuumizing the interior of the first supply pipe, the interior of the connection pipe, and the interior of the second supply pipe.

20. A non-transitory computer-readable recording medium storing a program that causes, by a computer, a substrate processing apparatus to perform a process in a process chamber of the substrate processing apparatus, the process comprising:
(a) processing a substrate accommodated in a process chamber by supplying an inert gas into a tank storing a precursor via a first supply pipe, supplying the precursor from an interior of the tank into the process chamber via a second supply pipe connected to the first supply pipe by a connection pipe, and exhausting the precursor from the interior of the process chamber; and
(b) purging an interior of the first supply pipe, an interior of the connection pipe and an interior of the second supply pipe by alternately repeating:
supplying a heated inert gas into the first supply pipe, the connection pipe and the second supply pipe, and exhausting the heated inert gas; and
vacuumizing the interior of the first supply pipe, the interior of the connection pipe, and the interior of the second supply pipe.
